(19) United States
(12) Patent Application Publication
(10) Pub. No.: US 2010/0187601 A1
(43) Pub. Date: Jul. 29, 2010

(54) SEMICONDUCTOR DEVICE

(76) Inventors: Fujio Masuoka, Tokyo (JP); Tomohiko Kudo, Tokyo (JP)

Correspondence Address: BRINKS HOFER GILSON & LIONE, P.O. BOX 10395, CHICAGO, IL, 60610, US

(21) Appl. No.: 12/699,626

(22) Filed: Feb. 3, 2010

Related U.S. Application Data
(63) Continuation of application No. PCT/JP2007/073935, filed on Dec. 12, 2007.
(60) Provisional application No. 61/207,670, filed on Feb. 13, 2009.

(51) Int. Cl. H01L 29/78

(52) U.S. Cl. 257/329; 257/E29.262

(57) ABSTRACT

A hermetic compressor includes a closed vessel for storing lubricating oil, an electric-driving element, and a compressing element driven by the electric-driving element. The compressing element includes a cylinder block forming a compression chamber, a piton that reciprocates inside the compression chamber, and an oiling device for supplying the lubricating oil to an outer circumference of the piston. A first oil groove is concavely formed on the outer circumference of the piston, and a second oil groove is concavely formed on a side opposite to the compression chamber relative to the first oil groove. The second oil groove has a spatial volume same or greater than that of the first oil groove. An expanded clearance portion is provided such that a clearance between the piston and the cylindrical hole portion broadens from a top dead point to a bottom dead point.

### RELATED APPLICATIONS

Pursuant to 35 U.S.C. §119(e), this application claims the benefit of the filing date of Provisional U.S. Patent Application Ser. No. 61/207,670 filed on Feb. 13, 2009. This application is a continuation application of PCT/JP2007/073935 filed on Dec. 12, 2007. The entire contents of these applications are hereby incorporated by reference.

### TECHNICAL FIELD

The present invention relates to a semiconductor device, and more specifically to a semiconductor device having a surrounding gate transistor (SGT) which is a three-dimensional semiconductor.

### BACKGROUND ART

Through miniaturization of semiconductor devices using a planar transistor, the planar transistor is used in a wide range of fields, such as computers, communication devices, measurement devices, automatic control devices and domestic devices, as a low-power consumption, low-cost, high-throughput microprocessor, an ASIC, a microcomputer, and a low-cost, large-capacity memory. However, the planar transistor is two-dimensionally formed on a plane of a semiconductor substrate. Specifically, the planar transistor has a structure where a source, a gate and a drain thereof are arranged along a surface of a silicon substrate in a horizontal direction. In contrast, the SGT has a structure where a source, a gate and a drain thereof are arranged in a direction perpendicular to a surface of a silicon substrate while allowing the gate to surround a convex-shaped semiconductor layer (see, for example, FIG. 20 in the following Non-Patent Document 1). Therefore, the SGT can largely reduce an occupancy area as compared with the planar transistor. However, in the SGT, along with miniaturization of ultra-large-scale integrated circuits (ULSI), a gate length becomes shorter to provide a lower channel resistance, whereas, as a silicon pillar becomes miniaturized, a diffusion-layer resistance and a contact resistance, i.e., a parasitic resistance, become larger to cause a reduction in drive current. Thus, in a miniaturized SGT device, it is essential to further reduce a parasitic resistance.

There has been known a technique of reducing a contact resistance as a parasitic resistance of source and drain regions to achieve a higher-speed operation of the device, as disclosed, for example, in the following Patent Document 1. FIG. 21 shows an SGT structure disclosed in the Patent Document 1, which is intended to reduce the contact resistance. In an SGT, along with scaling down of a silicon pillar, a contact area between the silicon pillar and a contact to be connected to a top of the silicon pillar becomes smaller to cause an increase in contact resistance. Consequently, a drive current of the SGT is reduced. As measures against this problem, the Patent Document 1 discloses a structure for increasing the contact area between the silicon pillar and the contact so as to reduce the contact resistance. Specifically, the structure is configured to allow the contact to come into contact with not only a top surface of the silicon pillar but also a part of a side surface of the silicon pillar, so that the contact area between the silicon pillar and the contact is increased to reduce the contact resistance.

Non-Patent Document 1H. Takato et al., IEEE transaction on electron device, Vol. 38, No. 3, March 1991, pp 573-578

Patent Document 1 JP 2007-123415A

As an SGT structure for reducing the contact resistance, the Patent Document 1 proposes a structure where the contact area between the silicon pillar and the contact is set to become greater than an area of the top surface of the silicon pillar, to reduce the contact resistance. However, in order to actually achieve a higher-speed operation of an SGT constituting a ULSI, it is desirable that the contact resistance is less than a reference resistance of the SGT.

In view of the above circumstances, it is an object of the present invention to provide a semiconductor device capable of reducing a contact resistance as a parasitic resistance to solve the problem of lowering in operation speed of an SGT.

### SUMMARY OF THE INVENTION

In order to achieve the above object, according to a first aspect of the present invention, there is provided a semiconductor device which comprises: a first silicon pillar formed on a semiconductor substrate; a second silicon pillar formed on the first silicon pillar; a first insulator surrounding a part of a surface of the second silicon pillar; a gate surrounding the first insulator; a third silicon pillar formed on the second silicon pillar; a first silicide surrounding a part of a surface of the first silicon pillar; and a second silicide surrounding a part of a surface of the third silicon pillar, wherein each of a contact resistance formed by the first silicide and the first silicon pillar, and a contact resistance formed by the second silicide and the third silicon pillar, is less than a reference resistance of the semiconductor device.

According to a second aspect of the present invention, there is provided a semiconductor device which comprises: a second silicon pillar formed on a semiconductor substrate; a first insulator surrounding a part of a surface of the second silicon pillar; a gate surrounding the first insulator; a third silicon pillar formed on the second silicon pillar; and a second silicide surrounding a part of a surface of the third silicon pillar, wherein a contact resistance formed by the second silicide and the third silicon pillar is less than a reference resistance of the semiconductor device.

According to a third aspect of the present invention, there is provided a semiconductor device which comprises: a first silicon pillar formed on a semiconductor substrate; a second silicon pillar formed on the first silicon pillar; a first insulator surrounding a part of a surface of the second silicon pillar; a gate surrounding the first insulator; and a first silicide surrounding a part of a surface of the first silicon pillar, wherein a contact resistance formed by the first silicide and the first silicon pillar is less than a reference resistance of the semiconductor device.

As above, the present invention makes it possible to reduce a parasitic resistance of a semiconductor device element to provide a semiconductor device having a high-speed, low-power consumption ULSI.

### BRIEF DESCRIPTION OF THE DRAWINGS

FIG. 1 is a bird's-eye view showing a semiconductor device according to a first embodiment of the present invention.

FIG. 2 is a sectional view of the semiconductor device, taken along the line A-A′ in FIG. 1.

FIG. 3 is a top view of the semiconductor device in FIG. 1.

FIG. 4 is a sectional view of the semiconductor device, taken along the line B-B′ in FIG. 2.

FIG. 5 is a sectional view of the semiconductor device, taken along the line C-C′ in FIG. 2.

FIG. 6 is a sectional view of the semiconductor device, taken along the line D-D′ in FIG. 2.

FIG. 7 is a graph showing a relationship between a diameter W1 and a length L1 of a first silicon pillar 830 for satisfying a condition that a contact resistance formed by a silicide and the first silicon pillar 830 is less than a reference resistance in the semiconductor device in FIG. 1.

FIG. 8 is a graph showing a relationship between a diameter W2 and a length L2 of a third silicon pillar 820 for satisfying a condition that a contact resistance formed by a silicide and the third silicon pillar 820 is less than a reference resistance in the semiconductor device in FIG. 1.

FIG. 9 is a bird's-eye view showing a semiconductor device according to a second embodiment of the present invention.

FIG. 10 is a sectional view of the semiconductor device, taken along the line A-A′ in FIG. 9.

FIG. 11 is a top view of the semiconductor device in FIG. 9.

FIG. 12 is a sectional view of the semiconductor device, taken along the line B-B′ in FIG. 10.

FIG. 13 is a sectional view of the semiconductor device, taken along the line C-C′ in FIG. 10.

FIG. 14 is a graph showing a relationship between a diameter W2 and a length L2 of a third silicon pillar 820 for satisfying a condition that a contact resistance formed by a silicide and the third silicon pillar 820 is less than a reference resistance in the semiconductor device in FIG. 9.

FIG. 15 is a bird's-eye view showing a semiconductor device according to a third embodiment of the present invention.

FIG. 16 is a sectional view of the semiconductor device, taken along the line A-A′ in FIG. 15.

FIG. 17 is a top view of the semiconductor device in FIG. 15.

FIG. 18 is a sectional view of the semiconductor device, taken along the line B-B′ in FIG. 16.

FIG. 19 is a sectional view of the semiconductor device, taken along the line C-C′ in FIG. 16.

FIG. 20 is a graph showing a relationship between a diameter W1 and a length L1 of a first silicon pillar 830 for satisfying a condition that a contact resistance formed by a silicide and the first silicon pillar 830 is less than a reference resistance in the semiconductor device in FIG. 1.

FIG. 21 is a bird's-eye view showing one example of a conventional SGT.

FIG. 22 is a top view of the conventional SGT.

FIG. 23 is a sectional view of the conventional SGT, taken along the line I-I′ in FIG. 22.

### DETAILED DESCRIPTION OF THE PREFERRED EMBODIMENTS

With reference to the drawings, a semiconductor device of the present invention will now be specifically described.

### First Embodiment

### Semiconductor Device

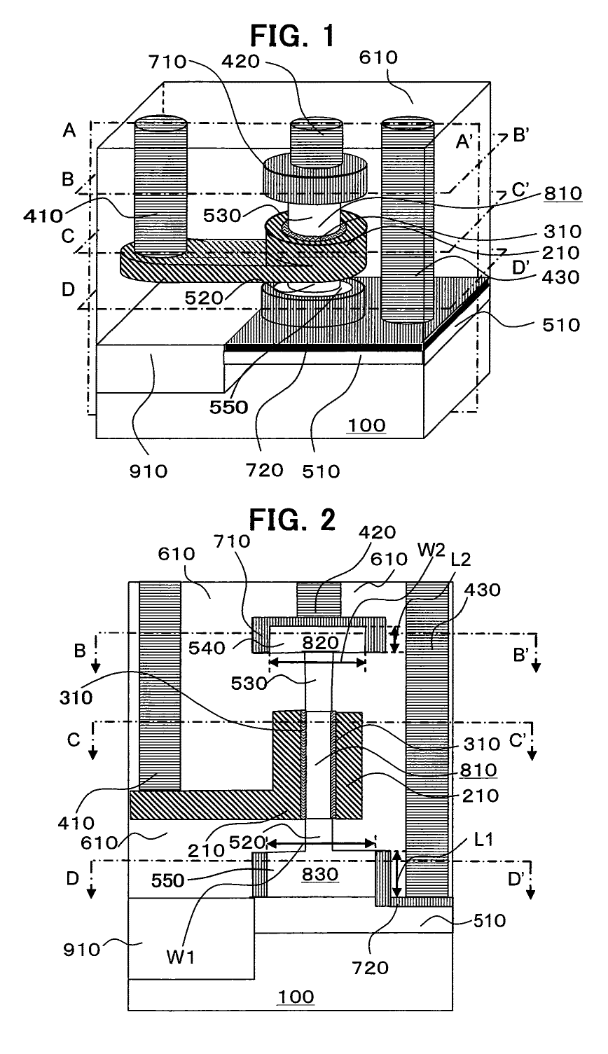

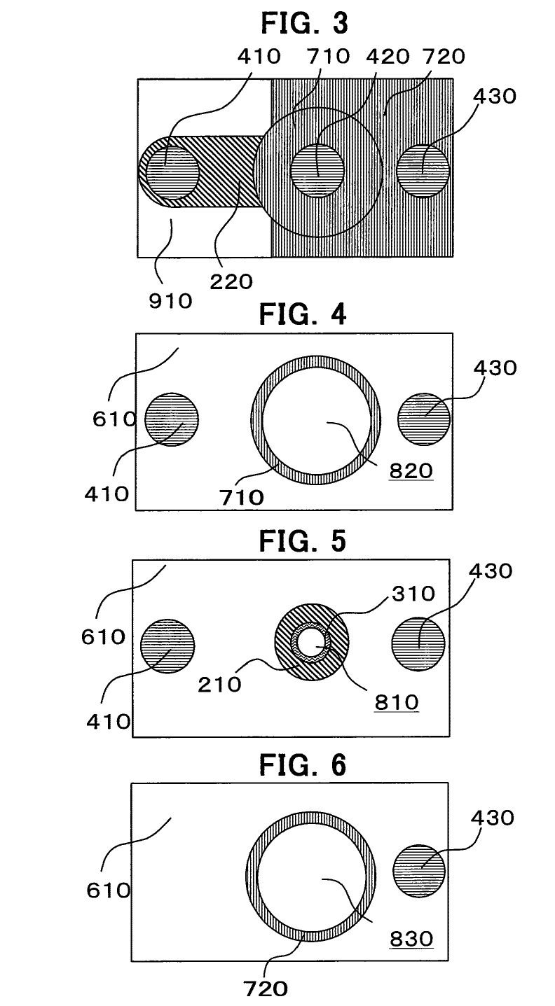

FIG. 1 is a schematic bird's-eye view showing a transistor of a semiconductor device according to a first embodiment of the present invention. FIG. 2 is a schematic sectional view taken along the line A-A′ in FIG. 1, and FIG. 3 is a top view of the transistor in FIG. 1. FIG. 4, FIG. 5 and FIG. 6 are a schematic sectional view taken along the line B-B′ in FIG. 2, a schematic sectional view taken along the line C-C′ in FIG. 2, and a schematic sectional view taken along the line D-D′ in FIG. 2, respectively. The semiconductor device according to the first embodiment comprises: a first silicon pillar 830 formed on a first conductive-type semiconductor substrate 100 to have a cross-sectionally circular shape; a second silicon pillar 810 formed on the first silicon pillar 830 to have a cross-sectionally circular shape; a first insulator 310 surrounding a part of a surface of the second silicon pillar 810; a gate 210 surrounding the first insulator 310; and a third silicon pillar 820 formed on the second silicon pillar 810 to have a cross-sectionally circular shape.

The second silicon pillar 810 includes a second conductive-type high-concentration impurity region 520 formed as a part of the second silicon pillar 810, and a second conductive-type high-concentration impurity region 530 formed as a part of the second silicon pillar 810.

The semiconductor substrate 100 includes a second conductive-type high-concentration impurity region 510 formed as a part of the semiconductor substrate 100, and a silicide region (first silicide) 720 formed as a part of the high-concentration impurity region 510. The semiconductor substrate 100 also has an element isolation region 910 formed therein.

The third silicon pillar 820 includes a second conductive-type high-concentration impurity region 540 formed as a part of the third silicon pillar 820, and a silicide region (second silicide) 710 is formed in the high-concentration impurity region 540.

The first silicon pillar 830 includes a second conductive-type high-concentration impurity region 550 formed as a part of the first silicon pillar 830.

The semiconductor device according to the first embodiment further comprises a contact 430 formed on the silicide region 720, a contact 420 formed on the silicide region 710, and a contact 410 formed on the gate 210.

Each of a contact resistance R1 formed by the first silicon pillar 830 including the high-concentration impurity region 510 and the silicide region 720 formed in the first silicon pillar 830, and a contact resistance R2 formed by the third silicon pillar 820 including the high-concentration impurity region 540 and the silicide region 710 formed in the third silicon pillar 830, is a parasitic resistance. In order to reduce the parasitic resistance, it is preferable that the contact resistances R1, R2 satisfy the following relational formulas (1-1), (1-2) with respect to a reference resistance Rs:

R1<Rs (1-1)

R2<Rs (1-2)

The reference resistance Rs is calculated according to the following formula (1-3) based on a current I (A) which flows between the contact 410 and the contact 430 in the above semiconductor device when 0 (V) is applied to one of the contacts 410, 430 and V (V) is applied to a remaining one of the contacts 410, 430, while applying V (V) to the contact 420, under a condition that the contact resistance R1=0 and the contact resistance R2=0:

Rs=V/I (1-3)

Specifically, when a length of the gate 210, a film thickness of the gate oxide layer, and a diameter of the second silicon pillar 810, are, respectively, 20 nm, 1 nm, and 10 nm, the parasitic resistance R1 of the first silicon pillar 830, a contact resistivity ρ_{C}, a sheet resistance ρ_{D} of a first conductive-type impurity region, a circumferential length K1 of a cross-section of the first silicon pillar 830, and a height dimension L1 of the first silicon pillar 830, satisfy the following formula (1-4), wherein α is expressed as the formula (1-5). Further, given that the circumferential length K1 (cm) of the cross-section of the first silicon pillar 830 satisfies the following relational formula (1-6) with respect to a diameter W1 (cm) of the first silicon pillar 830.

$$\begin{matrix}R 1 = \frac{{ρ}_{C}}{α K 1} coth ( \frac{L 1}{α} ) & ( 1 \text{-} 4 ) \\ α = {( \frac{{ρ}_{C}}{{ρ}_{D}} )}^{\frac{1}{2}} & ( 1 \text{-} 5 ) \\ K 1 = π W 1 & ( 1 \text{-} 6 )\end{matrix}$$

The parasitic resistance R2 of the third silicon pillar 820, a contact resistivity ρ_{C}, a sheet resistance ρ_{D} of a first conductive-type impurity region, a circumferential length K2 of a cross-section of the third silicon pillar 820, and a height dimension L2 of the third silicon pillar 820, satisfy the following formula (1-7). Further, given that the circumferential length K2 (cm) of the cross-section of the third silicon pillar 820 satisfies the following relational formula (1-8) with respect to a diameter W2 (cm) of the third silicon pillar 820.

$$\begin{matrix}R 2 = \frac{{ρ}_{C}}{α K 2} coth ( \frac{L 2}{α} ) & ( 1 \text{-} 7 ) \\ K 2 = π W 2 & ( 1 \text{-} 8 )\end{matrix}$$

The formula (1-4) is assigned to the formula (1-1), and the formula (1-7) is assigned to the formula (1-2), to obtain the following conditional formulas (1-9), (1-10):

$$\begin{matrix}\frac{{ρ}_{C}}{α K 1} coth ( \frac{L 1}{α} ) < {R}_{s} & ( 1 \text{-} 9 ) \\ \frac{{ρ}_{C}}{α K 2} coth ( \frac{L 2}{α} ) < {R}_{s} & ( 1 \text{-} 10 )\end{matrix}$$

As one example, given that the contact resistivity ρ_{C} and the sheet resistance ρ_{D}, are, respectively, 6.2e-8 (Ω-cm²) and 6.4e-3/W1 (Ω/sq.), and the current I (A) flowing between the contact 410 and the contact 430 in the above semiconductor device is 44 (μA) when 0 (V) is applied to one of the contacts 410, 430 and 1 (V) is applied to a remaining one of the contacts 410, 430, while applying 1 (V) to the contact 420, the reference resistance Rs is calculated as 2.3e-8 (Ω) according to the formula (1-3). These values are assigned to the formulas (1-9), (1-10) to obtain the following relational formula (1-11) between the height dimension L1 of the first silicon pillar 830 and the circumferential length K1 of the cross-section of the first silicon pillar 830, and the following relational formula (1-12) between the height dimension L2 (cm) of the third silicon pillar 820 and the circumferential length K2 (cm) of the cross-section of the third silicon pillar 820:

$$\begin{matrix}\frac{1}{W {1}^{3 / 2}} coth ( \frac{L 1}{W {1}^{1 / 2} \cdot 3.1 e - 3} ) < 3.6 e 9 & ( 1 \text{-} 11 ) \\ \frac{1}{W {2}^{3 / 2}} coth ( \frac{L 2}{W {2}^{1 / 2} \cdot 3.1 e - 3} ) < 3.6 e 9 & ( 1 \text{-} 12 )\end{matrix}$$

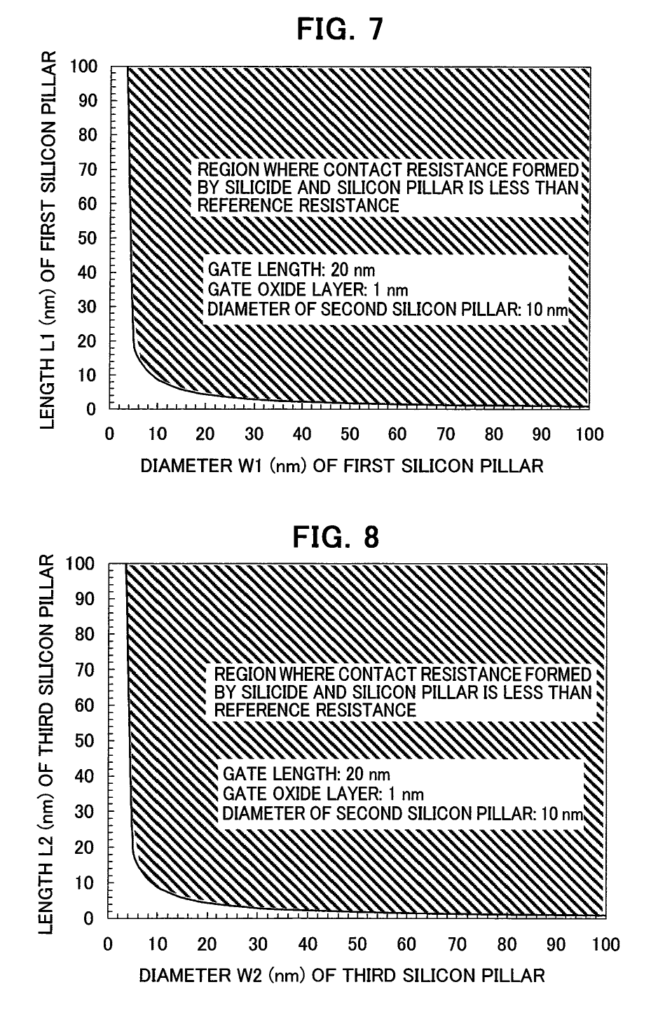

If these conditional formulas (1-11), (1-12) are satisfied, the formulas (1-1) are satisfied. Thus, the following formulas (1-13), (1-14) are obtained (see FIGS. 7 and 8):

$$\begin{matrix}\frac{1}{W {1}^{3 / 2}} coth ( \frac{L 1}{W {1}^{1 / 2} \cdot 3.1 e - 3} ) < 3.6 e 9 ⇒ R 1 < Rs & ( 1 \text{-} 13 ) \\ \frac{1}{W {2}^{3 / 2}} coth ( \frac{L 2}{W {2}^{1 / 2} \cdot 3.1 e - 3} ) < 3.6 e 9 ⇒ R 2 < Rs & ( 1 \text{-} 14 )\end{matrix}$$

As another example, given that a circumferential length of the second silicon pillar 810, each of the circumferential lengths of the third and first silicon pillars 820, 830 and the gate length are set, respectively, in the range of 8 nm to 100 μm, in the range of 8 nm to 100 μm and in the range of 6 nm to 10 μm. Further, given that the diameter of the second silicon pillar 810, the contact resistivity ρ_{C} and the sheet resistance ρ_{D} are, respectively, 2.6 nm, 7e-9 (Ω-cm²) and 6.4e-3/W1 (Ω/sq.), and the current I (A) flowing between the contact 410 and the contact 430 in the above semiconductor device is 11.4 (μA) when 0 (V) is applied to one of the contacts 410, 430 and 1 (V) is applied to a remaining one of the contacts 410, 430, while applying 1 (V) to the contact 420, the reference resistance Rs is calculated as 9.0e-8 (Ω) according to the formula (1-3). These values are assigned to the formulas (1-8), (1-9) to obtain the following formulas (1-15), (1-16):

$$\begin{matrix}\frac{1}{W {1}^{3 / 2}} coth ( \frac{L 1}{W {1}^{1 / 2} \cdot 1.1 e - 3} ) < 4.3 e 10 & ( 1 \text{-} 15 ) \\ \frac{1}{W {2}^{3 / 2}} coth ( \frac{L 2}{W {2}^{1 / 2} \cdot 1.1 e - 3} ) < 4.3 e 10 & ( 1 \text{-} 16 )\end{matrix}$$

If these conditional formulas (1-15), (1-16) are satisfied, the formulas (1-1), (1-2) are satisfied. Thus, the following formulas (1-17), (1-18) are obtained:

$$\begin{matrix}\frac{1}{W {1}^{3 / 2}} coth ( \frac{L 1}{W {1}^{1 / 2} \cdot 1.1 e - 3} ) < 4.3 e 10 ⇒ R 1 < Rs & ( 1 \text{-} 17 ) \\ \frac{1}{W {2}^{3 / 2}} coth ( \frac{L 2}{W {2}^{1 / 2} \cdot 1.1 e - 3} ) < 4.3 e 10 ⇒ R 2 < Rs & ( 1 \text{-} 18 )\end{matrix}$$

### Second Embodiment

### Semiconductor Device

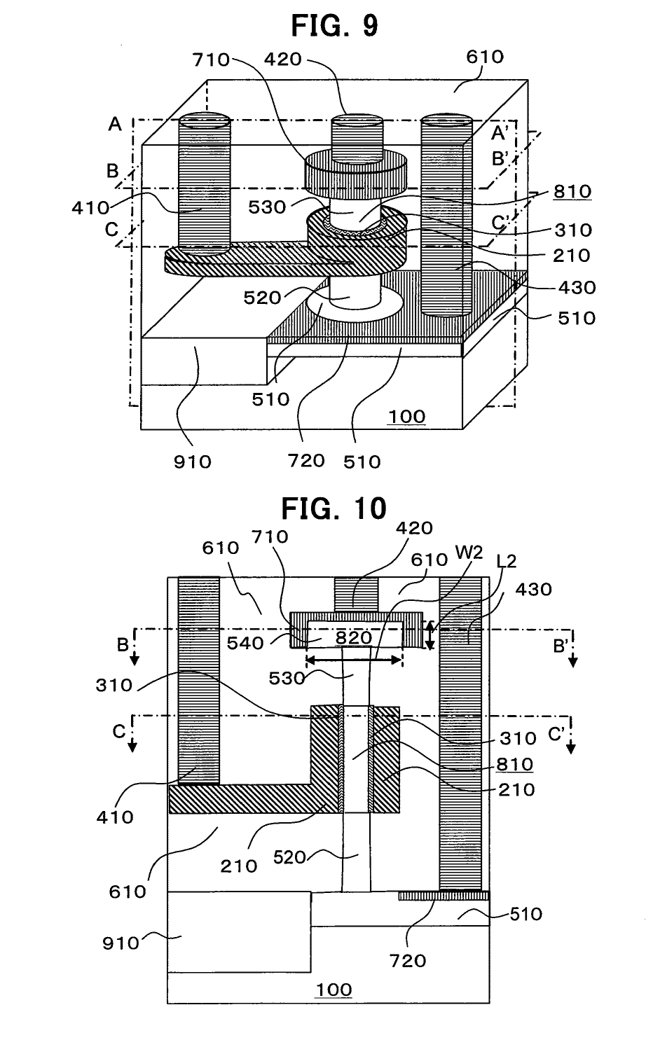

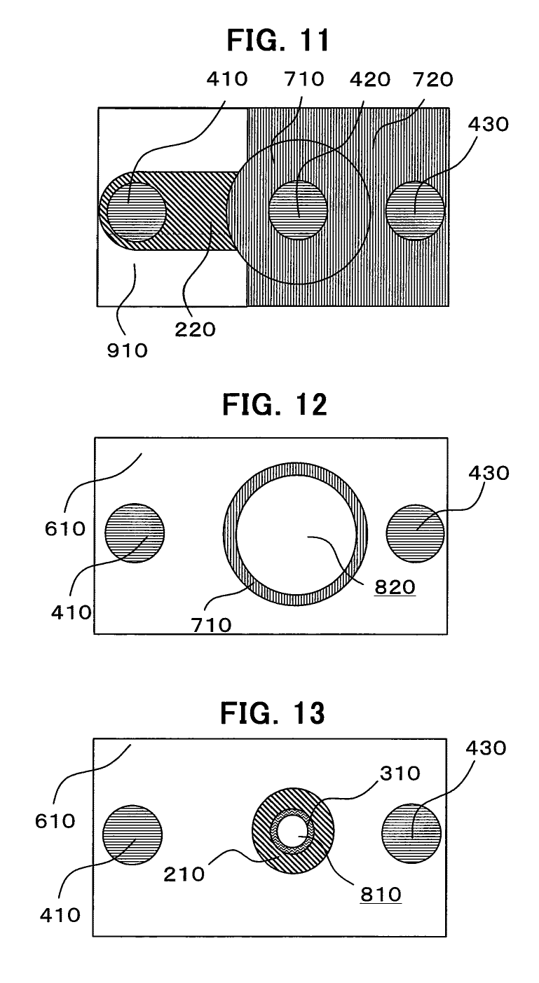

FIG. 9 is a schematic bird's-eye view showing a transistor of a semiconductor device according to a second embodiment of the present invention. FIG. 10 is a schematic sectional view taken along the line A-A′ in FIG. 9, and FIG. 11 is a top view of the transistor in FIG. 9. FIG. 12 is a schematic sectional view taken along the line B-B′ in FIG. 10, and FIG. 13 is a schematic sectional view taken along the line C-C′ in FIG. 10. The semiconductor device according to the second embodiment comprises a second silicon pillar 810 formed on a first conductive-type semiconductor substrate 100 to have a cross-sectionally circular shape, and a third silicon pillar 820 formed on the second silicon pillar 810 to have a cross-sectionally circular shape.

A part of a surface of the second silicon pillar 810 is surrounded by a first insulator 310, and the first insulator 310 is surrounded by a gate 210. The second silicon pillar 810 includes a second conductive-type high-concentration impurity region 520 formed as a part of the second silicon pillar 810, and a second conductive-type high-concentration impurity region 530 formed as a part of the second silicon pillar 810.

The semiconductor substrate 100 includes a second conductive-type high-concentration impurity region 510 formed as a part of the semiconductor substrate 100, and a silicide region (first silicide) 720 formed as a part of the high-concentration impurity region 510. The semiconductor substrate 100 also has an element isolation region 910 formed therein.

The third silicon pillar 820 includes a second conductive-type high-concentration impurity region 540 formed as a part of the third silicon pillar 820, and a silicide region (second silicide) 710 is formed in the high-concentration impurity region 540.

The semiconductor device according to the second embodiment further comprises a contact 430 formed on the silicide region 720, a contact 420 formed on the silicide region 710, and a contact 410 formed on the gate 210.

Differently from the first embodiment, on an assumption that a contact resistance R1 formed by the semiconductor substrate 100 including the high-concentration impurity region 510 and the silicide region 720 formed in the semiconductor substrate 100 is ignorable, the structure in the second embodiment is designed to satisfy the following formula (2-1):

R1<<Rs, R1<<R2 (2-1)

In this case, in order to reduce a contact resistance or parasitic resistance R2 formed by the third silicon pillar 820 including the high-concentration impurity region 540 and the silicide region 710 formed in the third silicon pillar 830, it is preferable that the contact resistance R2 and a reference resistance Rs satisfy the following formula (2-2):

R2<Rs (2-2)

The reference resistance Rs is calculated according to the following formula (2-3) based on a current I (A) which flows between the contact 410 and the contact 430 in the above semiconductor device when 0 (V) is applied to one of the contacts 410, 430 and V (V) is applied to a remaining one of the contacts 410, 430, while applying V (V) to the contact 420, under a condition that the contact resistance R1=0 and the contact resistance R2=0:

Rs=V/I (2-3)

Specifically, when a length of the gate 210, a film thickness of the gate oxide layer, and a diameter of the second silicon pillar 810, are, respectively, 20 nm, 1 nm, and 10 nm, the contact resistance R of the third silicon pillar 820, a contact resistivity ρ_{C}, a sheet resistance ρ_{D} of a first conductive-type impurity region, a circumferential length K2 of a cross-section of the third silicon pillar 820, and a height dimension L2 of the third silicon pillar 820, satisfy the following formula (2-4), wherein α is expressed as the formula (2-5). Further, given that the circumferential length K2 (cm) of the cross-section of the third silicon pillar 820 satisfies the following relational formula (2-6) with respect to a diameter W2 (cm) of the third silicon pillar 820.

$$\begin{matrix}R 2 = \frac{{ρ}_{C}}{α K 2} coth ( \frac{L 2}{α} ) & ( 2 \text{-} 4 ) \\ α = {( \frac{{ρ}_{C}}{{ρ}_{D}} )}^{\frac{1}{2}} & ( 2 \text{-} 5 ) \\ K 1 = π W 2 & ( 2 \text{-} 6 )\end{matrix}$$

The formula (2-4) is assigned to the formula (2-1) to obtain the following conditional formulas (2-7):

$$\frac{{ρ}_{C}}{α K 2} coth ( \frac{L 2}{α} ) < {R}_{s} \qquad ( 2 \text{-} 7 )$$

As one example, given that the contact resistivity ρ_{C} and the sheet resistance ρ_{D} are, respectively, 6.2e-8 (Ω-cm²) and 6.4e-3/W1 (Ω/sq.), and the current I (A) flowing between the contact 410 and the contact 430 in the above semiconductor device is 44 (μA) when 0 (V) is applied to one of the contacts 410, 430 and 1 (V) is applied to a remaining one of the contacts 410, 430, while applying 1 (V) to the contact 420, the reference resistance Rs is calculated as 2.3e-8 (Ω) according to the formula (2-3). These values are assigned to the formula (2-7) to obtain the following relational formula (2-8) between the height dimension L2 (cm) of the third silicon pillar 820 and the circumferential length K2 (cm) of the cross-section of the third silicon pillar 820:

$$\frac{1}{W {2}^{3 / 2}} coth ( \frac{L 2}{W {2}^{1 / 2} \cdot 3.1 e - 3} ) < 3.6 e 9 \qquad ( 2 \text{-} 8 )$$

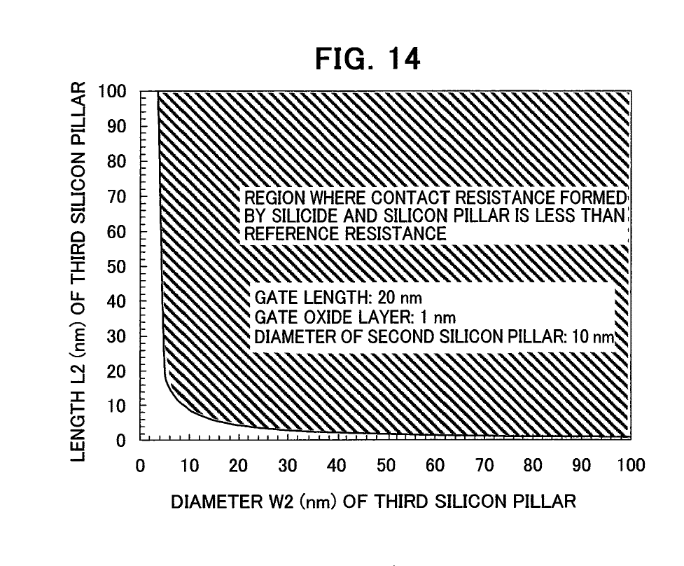

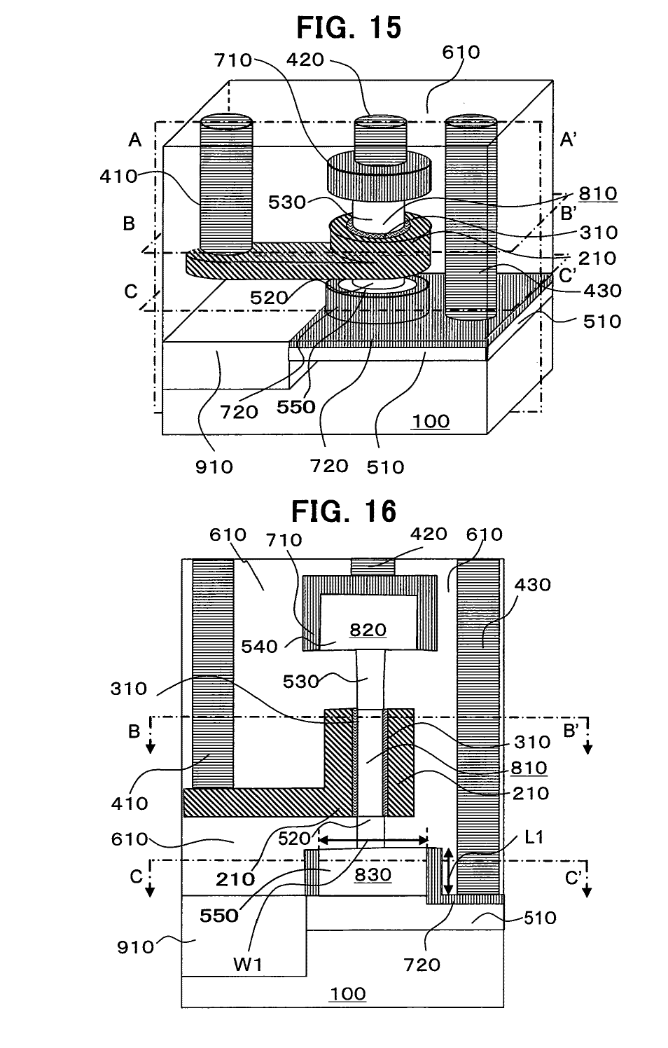

If the conditional formula (2-8) is satisfied, the formula (2-1) is satisfied. Thus, the following formula (2-9) is obtained (see FIG. 14):

$$\frac{1}{W {2}^{3 / 2}} coth ( \frac{L 2}{W {2}^{1 / 2} \cdot 3.1 e - 3} ) < 3.6 e 9 ⇒ R 2 < Rs \qquad ( 2 \text{-} 9 )$$

As another example, given that a circumferential length of each of the second and first silicon pillars 810, 830, the circumferential length of the third silicon pillar 820 and the gate length are set, respectively, in the range of 8 nm to 100 μm, in the range of 8 nm to 100 μm and in the range of 6 nm to 10 μm. Further, given that the diameter of the second silicon pillar 810, the contact resistivity ρ_{C} and the sheet resistance ρ_{D} are, respectively, 2.6 nm, 7e-9 (Ω-cm²) and 6.4e-3/W1 (Ω/sq.), and the current I (A) flowing between the contact 410 and the contact 430 in the above semiconductor device is 11.4 (μA) when 0 (V) is applied to one of the contacts 410, 430 and 1 (V) is applied to a remaining one of the contacts 410, 430, while applying 1 (V) to the contact 420, the reference resistance Rs is calculated as 9.0e-8 (Ω) according to the formula (2-3). Thus, the formula (2-7) is expressed as the following formula (2-10):

$$\frac{{ρ}_{C}}{α K 2} coth ( \frac{L 2}{α} ) < {R}_{s} \qquad ( 2 \text{-} 10 )$$

The above values are assigned to the formula (2-10) to obtain the following formula (2-11):

$$\frac{1}{W {2}^{3 / 2}} coth ( \frac{L 2}{W {2}^{1 / 2} \cdot 1.1 e - 3} ) < 4.3 e 10 \qquad ( 2 \text{-} 11 )$$

If the conditional formula (2-11) is satisfied, the formula (2-1) is satisfied. Thus, the following formula (2-12) is obtained:

$$\frac{1}{W {2}^{3 / 2}} coth ( \frac{L 2}{W {2}^{1 / 2} \cdot 1.1 e - 3} ) < 4.3 e 10 ⇒ R 2 < Rs \qquad ( 2 \text{-} 12 )$$

### Third Embodiment

### Semiconductor Device

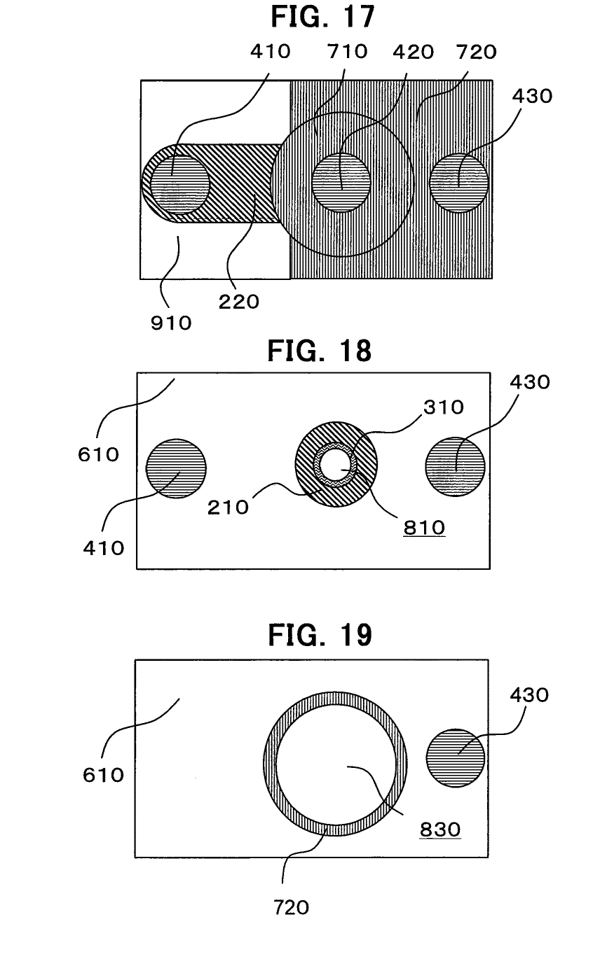

FIG. 15 is a schematic bird's-eye view showing a transistor of a semiconductor device according to a third embodiment of the present invention. FIG. 16 is a schematic sectional view taken along the line A-A′ in FIG. 15, and FIG. 17 is a top view of the transistor in FIG. 14 FIG. 18 is a schematic sectional view taken along the line B-B′ in FIG. 15 and FIG. 19 is a schematic sectional view taken along the line C-C′ in FIG. 15. The semiconductor device according to the third embodiment comprises: a first silicon pillar 830 formed on a first conductive-type semiconductor substrate 100 to have a cross-sectionally circular shape; a second silicon pillar 810 formed on the first silicon pillar 830 to have a cross-sectionally circular shape; a first insulator 310 surrounding a part of a surface of the second silicon pillar 810; a gate 210 surrounding the first insulator 310; and a third silicon pillar 820 formed on the second silicon pillar 810 to have a cross-sectionally circular shape.

The second silicon pillar 810 includes a second conductive-type high-concentration impurity region 520 formed as a part of the second silicon pillar 810, and a second conductive-type high-concentration impurity region 530 formed as a part of the second silicon pillar 810.

The semiconductor substrate 100 includes a second conductive-type high-concentration impurity region 510 formed as a part of the semiconductor substrate 100, and a silicide region (first silicide) 720 formed as a part of the high-concentration impurity region 510. The semiconductor substrate 100 also has an element isolation region 910 formed therein.

The third silicon pillar 820 includes a second conductive-type high-concentration impurity region 540 formed as a part of the third silicon pillar 820, and a silicide region (second silicide) 710 is formed in the high-concentration impurity region 540.

The first silicon pillar 830 includes a second conductive-type high-concentration impurity region 550 formed as a part of the first silicon pillar 830.

The semiconductor device according to the third embodiment further comprises a contact 430 formed on the silicide region 720, a contact 420 formed on the silicide region 710, and a contact 410 formed on the gate 210.

Differently from the first embodiment, on an assumption that a contact resistance R2 formed by the third silicon pillar 820 including the high-concentration impurity region 540 and the silicide region 710 formed in the third silicon pillar 830 is ignorable, the structure in the third embodiment is designed to satisfy the following formula (3-1):

R2<<Rs, R2<<Rs (3-1)

In this case, in order to reduce a contact resistance or parasitic resistance R1 formed by the first silicon pillar 830 including the high-concentration impurity region 510 and the silicide region 720 formed in the first silicon pillar 830, it is preferable that the contact resistance R1 and a reference resistance Rs satisfy the following formula (3-2):

R1<Rs (3-2)

The reference resistance Rs is calculated according to the following formula (3-3) based on a current I (A) which flows between the contact 410 and the contact 430 in the above semiconductor device when 0 (V) is applied to one of the contacts 410, 430 and V (V) is applied to a remaining one of the contacts 410, 430, while applying V (V) to the contact 420, under a condition that the contact resistance R1=0 and the contact resistance R2=0:

Rs=V/I (3-3)

Specifically, when a length of the gate 210, a film thickness of the gate oxide layer, and a diameter of the second silicon pillar 810, are, respectively, 20 nm, 1 nm, and 10 nm, the contact resistance R1 of the first silicon pillar 830, a contact resistivity ρ_{C}, a sheet resistance ρ_{D} of a first conductive-type impurity region, a circumferential length K1 of a cross-section of the first silicon pillar 830, and a height dimension L1 of the first silicon pillar 830, satisfy the following formula (3-4), wherein α is expressed as the formula (3-5). Further, given that the circumferential length K1 (cm) of the cross-section of the first silicon pillar 830 satisfies the following relational formula (3-6) with respect to a diameter W1 (cm) of the first silicon pillar 830.

$$\begin{matrix}R 1 = \frac{{ρ}_{C}}{α K 2} coth ( \frac{L 1}{α} ) & ( 3 \text{-} 4 ) \\ α = {( \frac{{ρ}_{C}}{{ρ}_{D}} )}^{\frac{1}{2}} & ( 3 \text{-} 5 ) \\ K 1 = π W 1 & ( 3 \text{-} 6 )\end{matrix}$$

The formula (3-4) is assigned to the formula (3-1) to obtain the following conditional formula (3-7):

$$\frac{{ρ}_{C}}{α K 1} coth ( \frac{L 1}{α} ) < {R}_{s} \qquad ( 3 \text{-} 7 )$$

As one example, given that the contact resistivity ρ_{C} and the sheet resistance ρ_{D} are, respectively, 6.2e-8 (Ω-cm²) and 1.6e-3×4/W1 (Ω/sq.), and the current I (A) flowing between the contact 410 and the contact 430 in the above semiconductor device is 44 (μA) when 0 (V) is applied to one of the contacts 410, 430 and 1 (V) is applied to a remaining one of the contacts 410, 430, while applying 1 (V) to the contact 420, the reference resistance Rs is calculated as 2.3e-8 (Ω) according to the formula (3-3). These values are assigned to the formula (3-7) to obtain the following relational formula (3-8) between the height dimension L1 of the first silicon pillar 830 and the circumferential length K1 of the cross-section of the first silicon pillar 830:

$$\frac{1}{W {1}^{3 / 2}} coth ( \frac{L 1}{W {1}^{1 / 2} \cdot 3.1 e - 3} ) < 3.6 e 9 \qquad ( 3 \text{-} 8 )$$

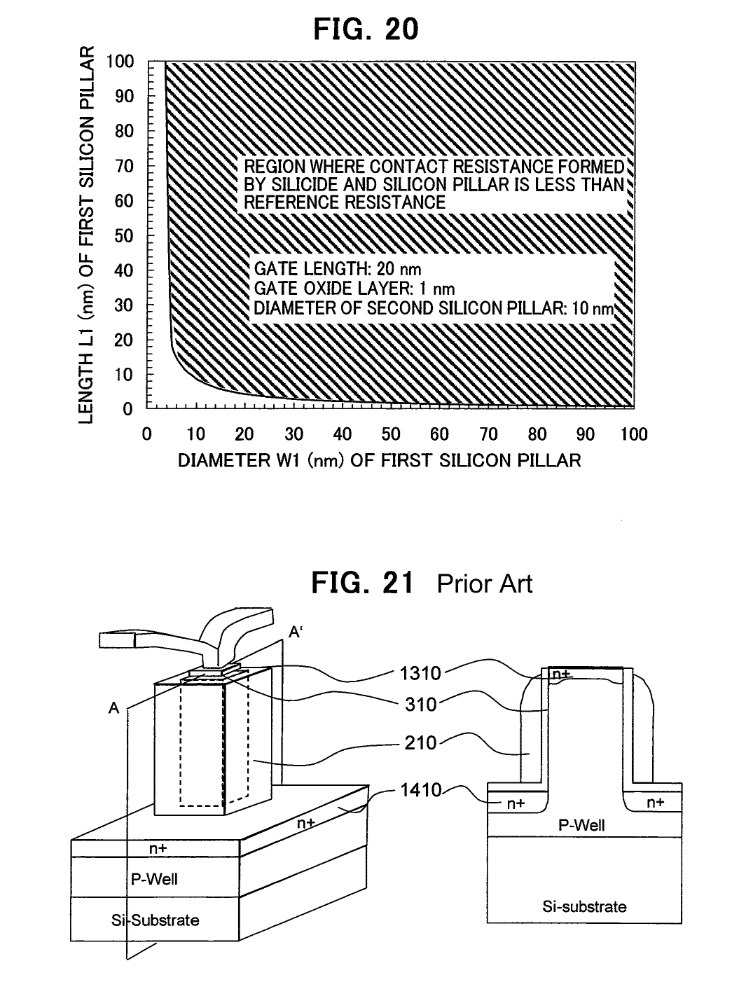

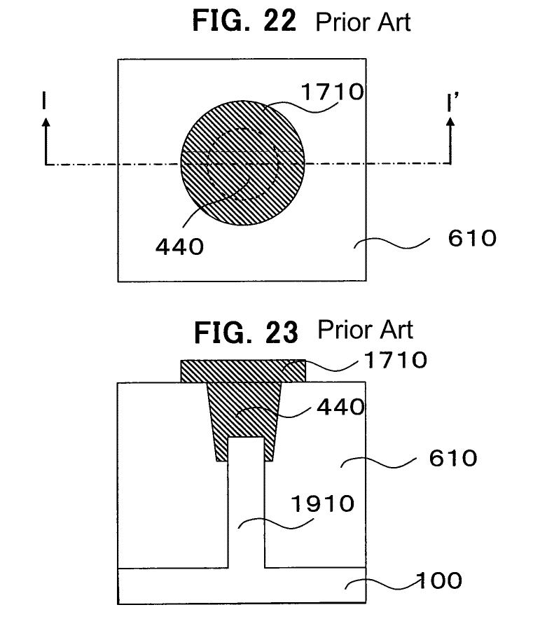

If the conditional formula (3-8) is satisfied, the formula (3-1) is satisfied. Thus, the following formula (3-9) is obtained (see FIG. 20):

$$\frac{1}{W {1}^{3 / 2}} coth ( \frac{L 1}{W {1}^{1 / 2} \cdot 3.1 e - 3} ) < 3.6 e 9 ⇒ R 1 < Rs \qquad ( 1 \text{-} 13 )$$

As another example, given that a circumferential length of each of the second and third silicon pillars 810, 820, the circumferential length of the first silicon pillar 830 and the gate length are set, respectively, in the range of 8 nm to 100 μm, in the range of 8 nm to 100 μm and in the range of 6 nm to 10 μm. Further, given that the diameter of the second silicon pillar 810, the contact resistivity ρ_{C} and the sheet resistance ρ_{D} are, respectively, 2.6 nm, 7e-9 (Ω-cm²) and 1.6e-3×4/W1 (Ω/sq.), and the current I (A) flowing between the contact 410 and the contact 430 in the above semiconductor device is 11.4 (μA) when 0 (V) is applied to one of the contacts 410, 430 and 1 (V) is applied to a remaining one of the contacts 410, 430, while applying 1 (V) to the contact 420, the reference resistance Rs is calculated as 9e-8 (Ω) according to the formula (3-3). Further, given that L1=L2 and K1=K2, the following formula (3-10) is obtained:

$$\frac{{ρ}_{C}}{α K 1} coth ( \frac{L 1}{α} ) < {R}_{s} \qquad ( 3 \text{-} 10 )$$

The above values are assigned to the formula (3-10) to obtain the following formula (3-11):

$$\frac{1}{W {1}^{3 / 2}} coth ( \frac{L 1}{W {1}^{1 / 2} \cdot 1.1 e - 3} ) < 4.3 e 10 \qquad ( 3 \text{-} 11 )$$

If the conditional formula (3-11) is satisfied, the formula (3-1) is satisfied. Thus, the following formula (3-12) is obtained:

$$\frac{1}{W {1}^{3 / 2}} coth ( \frac{L 1}{W {1}^{1 / 2} \cdot 1.1 e - 3} ) < 4.3 e 10 ⇒ R 1 < Rs \qquad ( 3 \text{-} 12 )$$

In the first to third embodiments, each of the first silicide region 710 and the second silicide region 720 may be made of one selected from the group consisting of nickel (Ni) silicide, platinum (Pt) silicide, erbium (Er) silicide, ytterbium (Yb) silicide and a combination of two or more thereof.

As mentioned above, the present invention provides a semiconductor device which comprises: a first silicon pillar formed on a semiconductor substrate; a second silicon pillar formed on the first silicon pillar; a first insulator surrounding a part of a surface of the second silicon pillar; a gate surrounding the first insulator; a third silicon pillar formed on the second silicon pillar; a first silicide surrounding a part of a surface of the first silicon pillar; and a second silicide surrounding a part of a surface of the third silicon pillar, wherein each of a contact resistance formed by the first silicide and the first silicon pillar, and a contact resistance formed by the second silicide and the third silicon pillar, is less than a reference resistance of the semiconductor device.

The present invention can provide a semiconductor device capable of solving problems of increase in power consumption and lowering in operation speed due to an increase in parasitic resistance of an SGT, to achieve high-speed SGT operation and low power consumption.

What is claimed is:

1. A semiconductor device comprising: a first silicon pillar formed on a semiconductor substrate; a second silicon pillar formed on the first silicon pillar; a first insulator surrounding a part of a surface of the second silicon pillar; a gate surrounding the first insulator; a third silicon pillar formed on the second silicon pillar; a first silicide formed at least on a side of the first silicon pillar; and a second silicide formed at least on a side of the third silicon pillar, wherein each of a contact resistance formed by the first silicide and the first silicon pillar, and a contact resistance formed by the second silicide and the third silicon pillar, is less than a reference resistance of the semiconductor device.

2. A semiconductor device comprising: a second silicon pillar formed on a semiconductor substrate; a first insulator surrounding a part of a surface of the second silicon pillar; a gate surrounding the first insulator; a third silicon pillar formed on the second silicon pillar; and a second silicide formed at least on a side of the third silicon pillar, wherein a contact resistance formed by the second silicide and the third silicon pillar is less than a reference resistance of the semiconductor device.

3. A semiconductor device comprising: a first silicon pillar formed on a semiconductor substrate; a second silicon pillar formed on the first silicon pillar; a first insulator surrounding a part of a surface of the second silicon pillar; a gate surrounding the first insulator; and a first silicide formed at least on a side of the first silicon pillar, wherein a contact resistance formed by the first silicide and the first silicon pillar is less than a reference resistance of the semiconductor device.

4. A semiconductor device comprising: a first silicon pillar formed on a semiconductor substrate; a second silicon pillar formed on the first silicon pillar;
a first insulator surrounding a part of a surface of the second silicon pillar; a gate surrounding the first insulator; a third silicon pillar formed on the second silicon pillar; a first silicide formed at least on a side of the first silicon pillar; and a second silicide formed at least on a side of the third silicon pillar, wherein a diameter W1 (cm) and a height dimension L1 (cm) of the first silicon pillar, and a diameter W2 (cm) and a height dimension L2 (cm) of the third silicon pillar, satisfy the following relations:
$$\frac{1}{W {1}^{3 / 2}} coth ( \frac{L 1}{W {1}^{1 / 2} \cdot 1.1 e - 3} ) < 4.3 e 10 , and$$
$$\frac{1}{W {2}^{3 / 2}} coth ( \frac{L 1}{W {2}^{1 / 2} \cdot 1.1 e - 3} ) < 4.3 e 10$$

5. A semiconductor device comprising: a second silicon pillar formed on a semiconductor substrate; a first insulator surrounding a part of a surface of the second silicon pillar; a gate surrounding the first insulator; a third silicon pillar formed on the second silicon pillar; and a second silicide formed at least on a side of the third silicon pillar, wherein a diameter W2 (cm) and a height dimension L2 (cm) of the third silicon pillar satisfy the following relation:
$$\frac{1}{W {2}^{3 / 2}} coth ( \frac{L 2}{W {2}^{1 / 2} \cdot 1.1 e - 3} ) < 4.3 e 10$$

6. A semiconductor device comprising: a first silicon pillar formed on a semiconductor substrate; a second silicon pillar formed on the first silicon pillar; a first insulator surrounding a part of a surface of the second silicon pillar; a gate surrounding the first insulator; and a first silicide formed at least on a side of the first silicon pillar, wherein a diameter W1 (cm) and a height dimension L1 (cm) of the first silicon pillar satisfy the following relation:
$$\frac{1}{W {1}^{3 / 2}} coth ( \frac{L 1}{W {1}^{1 / 2} \cdot 1.1 e - 3} ) < 4.3 e 10$$

7. The semiconductor device as defined in claim 1, wherein each of the first silicide and the second silicide is one selected from the group consisting of nickel (Ni) silicide, platinum (Pt) silicide, erbium (Er) silicide, ytterbium (Yb) silicide and a combination of two or more thereof.

8. The semiconductor device as defined in claim 2, wherein each of the first silicide and the second silicide is one selected from the group consisting of nickel (Ni) silicide, platinum (Pt) silicide, erbium (Er) silicide, ytterbium (Yb) silicide and a combination of two or more thereof.

9. The semiconductor device as defined in claim 3, wherein each of the first silicide and the second silicide is one selected from the group consisting of nickel (Ni) silicide, platinum (Pt) silicide, erbium (Er) silicide, ytterbium (Yb) silicide and a combination of two or more thereof.

10. The semiconductor device as defined in claim 4, wherein each of the first silicide and the second silicide is one selected from the group consisting of nickel (Ni) silicide, platinum (Pt) silicide, erbium (Er) silicide, ytterbium (Yb) silicide and a combination of two or more thereof.

11. The semiconductor device as defined in claim 5, wherein each of the first silicide and the second silicide is one selected from the group consisting of nickel (Ni) silicide, platinum (Pt) silicide, erbium (Er) silicide, ytterbium (Yb) silicide and a combination of two or more thereof.

12. The semiconductor device as defined in claim 6, wherein each of the first silicide and the second silicide is one selected from the group consisting of nickel (Ni) silicide, platinum (Pt) silicide, erbium (Er) silicide, ytterbium (Yb) silicide and a combination of two or more thereof.

13. The semiconductor device as defined in claim 1, wherein each of the first silicon pillar and the third silicon pillar includes a high-concentration impurity region.

14. The semiconductor device as defined in claim 2, wherein each of the first silicon pillar and the third silicon pillar includes a high-concentration impurity region.

15. The semiconductor device as defined in claim 3, wherein each of the first silicon pillar and the third silicon pillar includes a high-concentration impurity region.

16. The semiconductor device as defined in claim 4, wherein each of the first silicon pillar and the third silicon pillar includes a high-concentration impurity region.

17. The semiconductor device as defined in claim 5, wherein each of the first silicon pillar and the third silicon pillar includes a high-concentration impurity region.

18. The semiconductor device as defined in claim 6, wherein each of the first silicon pillar and the third silicon pillar includes a high-concentration impurity region.
